(19) United States
(12) Patent Application Publication
(10) Pub. No.: US 2025/0118707 A1
(43) Pub. Date: Apr. 10, 2025

(54) INTEGRATED CIRCUIT PACKAGES AND METHODS

(71) Applicant: Taiwan Semiconductor Manufacturing Co., Ltd., Hsinchu (TW)

(72) Inventors: Po-Cheng Chen, Hsinchu (TW); Chao-Wen Shih, Zhubei City (TW); Min-Chien Hsiao, Taichung City (TW); Kuo-Chiang Ting, Hsinchu (TW); Yen-Ming Chen, Chu-Pei City (TW)

(21) Appl. No.: 18/482,632

(22) Filed: Oct. 6, 2023

(51) Int. Cl. H01L 25/065; H01L 23/00; H01L 23/31; H01L 23/498

(52) U.S. Cl. CPC H01L 25/0652; H01L 23/3128; H01L 23/49816; H01L 24/13; H01L 24/29; H01L 2224/13007; H01L 2224/13025; H01L 2224/29011; H01L 2224/29021; H01L 2924/1431; H01L 2924/1435; H01L 2924/15311; H01L 2924/182

(57) ABSTRACT

An integrated circuit package and the method of forming the same are provided. The integrated circuit package may include a first die, a first gap-fill layer along sidewalls of the first die, a first bonding layer on the first die and the first gap-fill layer, and a first die connector in the first bonding layer. The first die connector may be directly over an interface between the first die and the first gap-fill layer.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A, 3B, 3C, 4A, 4B, 5, 6, 7, 8, 9, and 10 illustrate cross-sectional views and top-down views of intermediate stages in the formation of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit package with dummy bond pads over interfaces between a semiconductor device and an encapsulant, and a method of forming the same are provided. In accordance with some embodiments, one or more lower integrated circuit dies may be encapsulated in a lower gap-fill layer, and a bonding layer may be formed on top surfaces of the lower gap-fill layer and the lower integrated circuit dies. Die connectors are disposed in the bonding layer, including one or more dummy die connectors located over interfaces between the lower integrated circuit dies and the lower gap-fill layer. One or more upper integrated circuit dies are bonded to the bonding layer and the die connectors, wherein the upper integrated circuit dies may be directly over interfaces between the lower integrated circuit dies and the lower gap-fill layer. By forming the dummy die connectors directly over interfaces between the lower integrated circuit dies and the lower gap-fill layer, the effect of the coefficient of thermal expansion (CTE) mismatch between the lower integrated circuit dies and the lower gap-fill layer on the bonding integrity between the upper integrated circuit dies and the bonding layer as well as the die connectors may be eliminated or reduced, thereby eliminating or reducing the risk of the delamination of the upper integrated circuit dies during the manufacturing and the operation of the integrated circuit package. As a result, better reliability of the integrated circuit package may be achieved

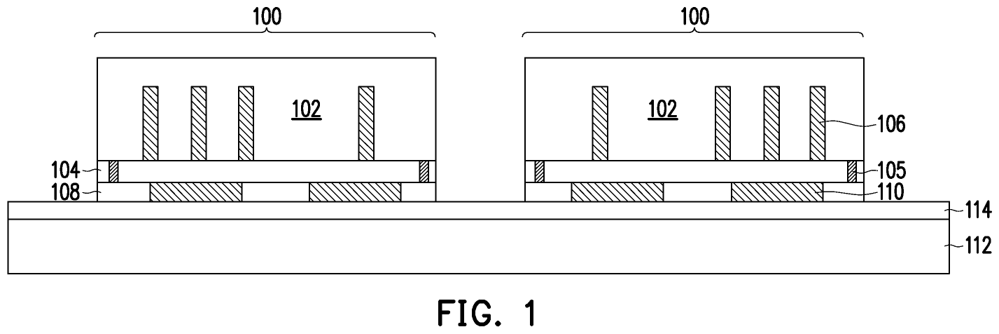

FIGS. 1-10 illustrate intermediate processing steps in forming an integrated circuit package. Referring first to FIG. 1, lower integrated circuit dies 100 are attached to a carrier 112 by an adhesive 114. The carrier 112 may be a semiconductor carrier, a glass carrier, a ceramic carrier, or the like. The carrier 112 may be a wafer. In some embodiments, the adhesive 114 is a thermal-release layer, such as an epoxy-based light-to-heat-conversion (LTHC) release material, which loses its adhesive property when heated. In some embodiments, the adhesive 114 is a UV glue, which loses its adhesive property when exposed to UV light. The layout of the lower integrated circuit dies 100 over the carrier 112 shown in FIG. 1 is an example, and other layouts are contemplated.

Each lower integrated circuit die 100 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or combinations thereof.

Each lower integrated circuit die 100 may have a semiconductor substrate 102, such as silicon, doped or undoped, or an active layer of a semiconductor-on-insulator (SOI) substrate. The semiconductor substrate 102 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. Other substrates, such as multi-layered or gradient substrates, may also be used. The semiconductor substrate 102 may have an active surface (e.g., the surface facing downwards in FIG. 1), which may be called a front side, and an inactive surface (e.g., the surface facing upwards in FIG. 1), which may be called a back side. The back side of the semiconductor substrate 102 may also be referred to as a back side of the lower integrated circuit die 100 and the front side of the semiconductor substrate 102 may face a front side of the lower integrated circuit die 100.

Devices (not separately illustrated) may be disposed at the active surface of the semiconductor substrate 102. The devices may be active devices (e.g., transistors, diodes, etc.), capacitors, resistors, or the like. An interconnect structure 104 may be disposed on the active surface of the semiconductor substrate 102. The interconnect structure 104 may interconnect the devices to form an integrated circuit. The interconnect structure 104 may comprise metallization patterns (not separately shown) in dielectric layers (not separately shown). The dielectric layers may be low-k dielectric layers. The metallization patterns may include metal lines and vias, which may be formed in the dielectric layers by a damascene process, such as a single damascene process, a dual damascene process, or the like. The metallization patterns may be formed of a suitable conductive material, such as copper, tungsten, aluminum, silver, gold, a combination thereof, or the like. The metallization patterns may be electrically coupled to the devices. A seal ring 105 may extend through the interconnect structure 104 of each lower integrated circuit die 100. The seal ring 105 may encircle the metallization patterns of the corresponding interconnect structure 104 in a top-down view and a region between the seal ring 105 and the metallization patterns may be referred to as a keep-out zone (KOZ). The seal ring 105 may be formed of the same or similar material and by the same or similar process as the metallization patterns. The seal ring 105 may be electrically isolated from the devices.

Conductive vias 106 may be disposed in the semiconductor substrate 102. The conductive vias 106 may be electrically coupled to the metallization patterns of the interconnect structure 104. The semiconductor substrate 102 may be thinned in a subsequent process to expose the conductive vias 106 at the inactive surface of the semiconductor substrate 102. After the thinning process, the conductive vias 106 may be through-substrate vias (TSV), such as through-silicon vias. In some embodiments, the conductive vias 106 are formed by a via-first process, such that the conductive vias 106 may extend into the semiconductor substrate 102 but not into the interconnect structure 104. The conductive vias 106 formed by a via-first process may be connected to a lower metallization pattern (e.g., closer to the semiconductor substrate 102) of the interconnect structure 104. In some embodiments, the conductive vias 106 are formed by a via-middle process, such that the conductive vias 106 may extend through a portion of the interconnect structure 104 and into the semiconductor substrate 102. The conductive vias 106 formed by a via-middle process may be connected to a middle metallization pattern of the interconnect structure 104. In some embodiments, the conductive vias 106 are formed by a via-last process, such that the conductive vias 106 may extend through an entirety of the interconnect structure 104 and into the semiconductor substrate 102. The conductive vias 106 formed by a via-last process may be connected to an upper metallization pattern (e.g., further from the semiconductor substrate 102) of the interconnect structure 104.

A bonding layer 108 may be disposed on the interconnect structure 104 at the front side of each lower integrated circuit die 100. The bonding layer 108 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; or the like. The bonding layer 108 may be formed by chemical vapor deposition (CVD), atomic layer deposition (ALD), or the like. One or more passivation layer(s) (not separately illustrated) may be disposed between the bonding layer 108 and the interconnect structure 104.

Die connectors 110 may extend through the bonding layer 108 and be electrically coupled to metallization patterns of the interconnect structure 104. The die connectors 110 may include conductive pillars, conductive pads, or the like, to which external connections can be made. In some embodiments, the die connectors 110 include conductive pads at the front side of the lower integrated circuit die 100 and conductive vias that connect the conductive pads to the upper metallization pattern of the interconnect structure 104. In such embodiments, the die connectors 110, including the conductive pads and the conductive vias, may be formed by a damascene process, such as a single damascene process, a dual damascene process, or the like. The die connectors 110 may be formed of a conductive material, such as copper, aluminum, or the like, by a suitable coating process, such as plating or the like.

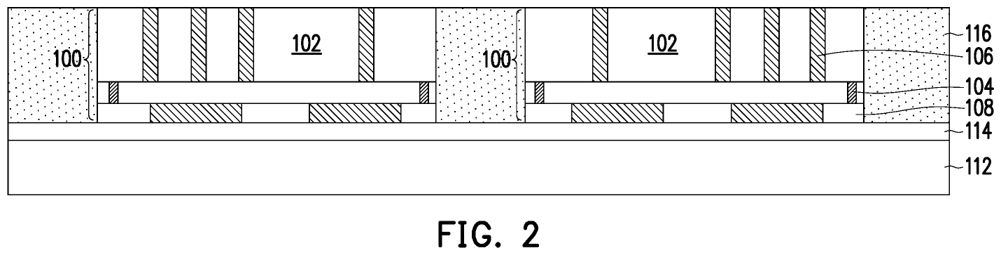

In FIG. 2, a lower gap-fill layer 116 is formed around the lower integrated circuit dies 100 and the semiconductor substrates 102 of the lower integrated circuit dies 100 are thinned to expose the conductive vias 106. The lower gap-fill layer 116 may encircle the lower integrated circuit dies 100 in the top-down view. The lower gap-fill layer 116 may extend along sidewalls of the lower integrated circuit dies 100 (e.g., the semiconductor substrates 102, the interconnect structure 104, and the bonding layer 108). The lower gap-fill layer 116 may have a different CTE from components of the lower integrated circuit dies 100 (e.g., the semiconductor substrates 102). The lower gap-fill layer 116 may be an insulating layer and may be formed of a dielectric material, such as silicon oxide, PSG, BSG, BPSG, a TEOS based oxide, or the like, which may be formed by a suitable deposition process such as CVD, ALD, or the like. Initially, the lower gap-fill layer 116 may cover the back sides of the lower integrated circuit dies 100. A first thinning process may be performed to level surfaces of the lower gap-fill layer 116 with the back side surface of the lower integrated circuit dies 100. The first thinning process may be a chemical-mechanical polishing (CMP) process, a grinding process, an etch-back process, combinations thereof, or the like.

The semiconductor substrates 102 are thinned to expose the conductive vias 106 by a second thinning process. Portions of the lower gap-fill layer 116 may also be removed by the second thinning process. The second thinning process may be, a CMP, a grinding process, an etch-back process, combinations thereof, or the like, which is performed at the back sides of the lower integrated circuit dies 100. After the second thinning process, surfaces of the lower gap-fill layer 116, the lower integrated circuit dies 100 (including the semiconductor substrates 102 and the conductive vias 106) are substantially coplanar (within process variations).

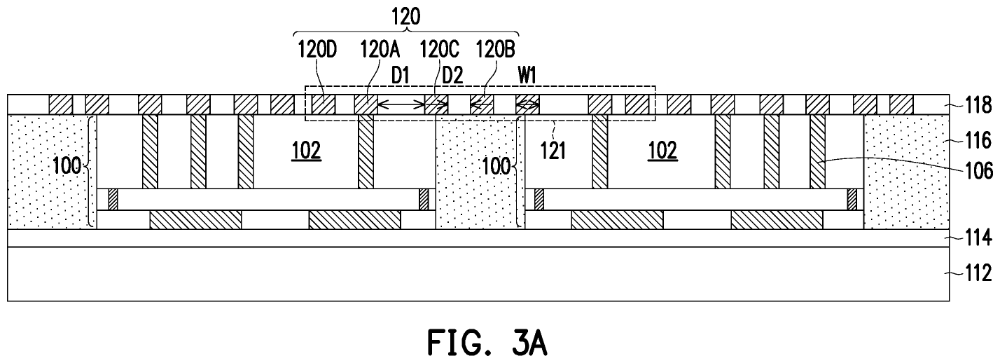

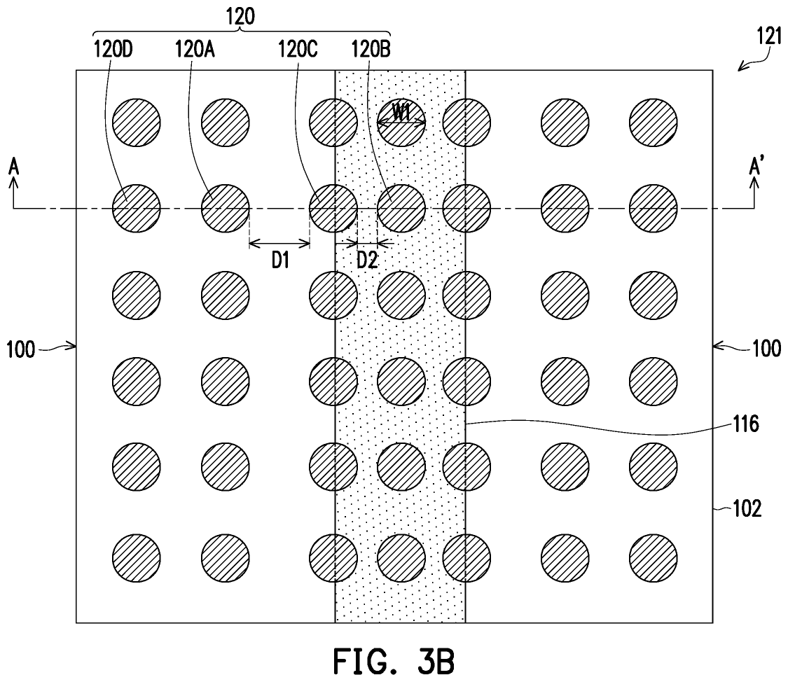

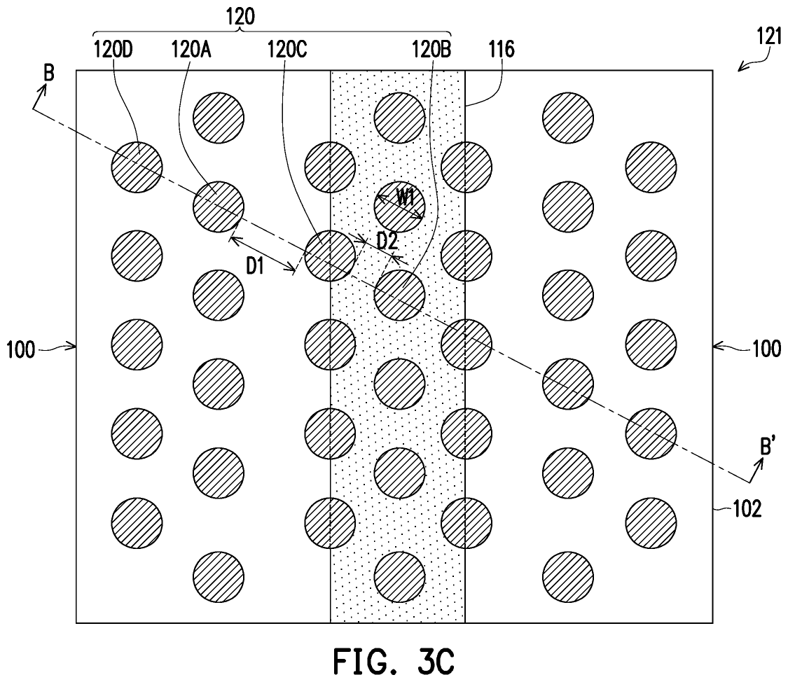

In FIG. 3A, a bonding layer 118 is formed on the lower gap-fill layer 116 and the back sides of the lower integrated circuit dies 100, and die connectors 120 are formed in the bonding layer 118. The die connectors 120 may be also referred to as bonding pads, which may be used for bonding with upper integrated circuit dies in a subsequent process. The die connectors 120 may comprise active die connectors 120A, dummy die connectors 120B, dummy die connectors 120C, and dummy die connectors 120D. The active die connectors 120A may be the die connectors 120 that are in electrically coupled with the conductive vias 106 and the circuitry of the lower integrated circuit dies 100. The dummy die connectors 120B, the dummy die connectors 120C, and the dummy die connectors 120D may be the die connectors 120 that are electrically isolated from the circuitry of the lower integrated circuit dies 100.

The dummy die connectors 120B and the dummy die connectors 120D may be directly over the lower gap-fill layer 116 and the semiconductor substrate 102, respectively. As described in greater details below, after bonding with the upper integrated circuit dies, the dummy die connectors 120B may be completely covered by the upper integrated circuit dies and the dummy die connectors 120D may be partially covered by the upper integrated circuit dies. The dummy die connectors 120D may be referred to as landing structures. The dummy die connectors 120C may be directly over interfaces between the lower integrated circuit dies 100 and the lower gap-fill layer 116. In some embodiments, the dummy die connectors 120C may be between the corresponding active die connectors 120A and dummy die connectors 120B, wherein the active die connector 120A and the dummy die connector 120B are the closest die connectors 120 to the dummy die connector 120C on each side. As discussed in greater details below, forming the dummy die connectors 120C directly over interfaces between the lower integrated circuit dies 100 and the lower gap-fill layer 116 may eliminate or reduce the effect of the CTE mismatch between the materials underneath, such as between the components of the lower integrated circuit dies 100 (e.g., the semiconductor substrates 102) and the lower gap-fill layer 116 on the bonding integrity between the upper integrated circuit dies and the bonding layer 118 as well as the die connectors 120.

The die connectors 120 may have a width W1 in a range from about 3 μm to about 4 μm, such as about 3.5 μm. The dummy die connector 120C may be spaced apart from the closest active die connector 120A by a distance D1. The dummy die connector 120C may be spaced apart from the closest dummy die connector 120B by a distance D2. In the embodiments illustrated in FIG. 3A, the distance D1 is different from the distance D2. For example, the distance D1 may be in range from about 4 μm to about 6 μm, such as about 4.82 μm and the distance D2 may be in range from about 1 μm to about 2 μm, such as about 1.32 μm, wherein the distance D1 is larger than the distance D2. In other embodiments, the distance D1 is equal to the distance D2. For example, the distance D1 and the distance D2 may be in range from about 2 μm to about 4 μm, such as about 3.07 μm.

In the embodiments illustrated in FIG. 3A, the die connectors 120 extend completely through the bonding layer 118 from a top surface of the bonding layer 118 to a bottom surface of the bonding layer 118. As a result, the active die connectors 120A may be in contact with the semiconductor substrate 102 and the conductive vias 106, the dummy die connectors 120B may be in contact with the lower gap-fill layer 116, the dummy die connectors 120C may be in contact with the semiconductor substrate 102 and the lower gap-fill layer 116, including the interfaces between the lower integrated circuit dies 100 and the lower gap-fill layer 116. In other embodiments, the die connectors 120 may extend partially through the bonding layer 118 from a top surface of the bonding layer 118 to a certain depth into the bonding layer 118 and the conductive vias 106 may protrude from the surface of the semiconductor substrate 102 and extend partially through the bonding layer 118 to contact the active die connectors 120A in the bonding layer 118.

The bonding layer 118 may be formed of an oxide such as silicon oxide, PSG, BSG, BPSG, a TEOS based oxide, or the like, which may be formed by a suitable deposition process such as CVD, ALD, or the like. The die connectors 120 may be formed by a damascene process, such as a single damascene process, a dual damascene process, or the like. The die connectors 120 may be formed of a metal, such as copper, aluminum, or the like, which can be formed by plating or the like. In some embodiments, a planarization process such as a CMP, a grinding process, an etch-back process, combinations thereof, or the like, is performed on the bonding layer 118 and the die connectors 120. After the planarization process, surfaces of the bonding layer 118 and the die connectors 120 may be substantially coplanar (within process variations).

FIG. 3B shows a top-down view of a region 121 of the structure shown in FIG. 3A in accordance with some embodiments, in which the die connectors 120 are in an array. The cross-sectional view shown in FIG. 3A may be obtained along reference cross-section A-A′ in FIG. 3B. The bonding layer 118 is omitted and the portions of the interfaces between the lower integrated circuit dies 100 and the lower gap-fill layer 116 underneath the dummy die connectors 120C are shown in dash lines in FIG. 3B for illustrative purposes. As shown in FIG. 3B, the die connectors 120 may form an array comprising columns of the active die connectors 120A, the dummy die connectors 120B, the dummy die connectors 120C, and the dummy die connectors 120D. The columns of the dummy die connectors 120C may be over the interfaces between the lower integrated circuit dies 100 and the lower gap-fill layer 116 as well as between corresponding columns of the active die connectors 120A and the dummy die connectors 120B. Each dummy die connector 120C may be divided by the interface between the semiconductor substrate 102 and the lower gap-fill layer 116 into a first portion over the semiconductor substrate 102 and a second portion over the lower gap-fill layer 116. In the embodiments illustrated in FIG. 3B, the first portion and the second portion of the dummy die connector 120C are of a same width and size. In other embodiments, the first portion and the second portion of the dummy die connector 120C are of different widths and sizes. FIG. 3B illustrates each die connectors 120 having a shape of a circle as an example, and other shapes are contemplated. FIG. 3B illustrates one column of the dummy die connectors 120B between the two columns of the dummy die connectors 120C as an example, and other numbers of columns of the dummy die connectors 120B may be between the two columns of the dummy die connectors 120C.

FIG. 3C shows a top-down view of a region 121 of the structure shown in FIG. 3A in accordance with some embodiments, in which the die connectors 120 are in a staggered array. The cross-sectional view shown in FIG. 3A may be obtained along reference cross-section B-B′ in FIG. 3C. The top-down view shown in FIG. 3C is similar to the top-down view shown in FIG. 3B, wherein like reference numerals refer to like features. As shown in FIG. 3C, the die connectors 120 may form a staggered array comprising columns of the active die connectors 120A, the dummy die connectors 120B, the dummy die connectors 120C, and the dummy die connectors 120D.

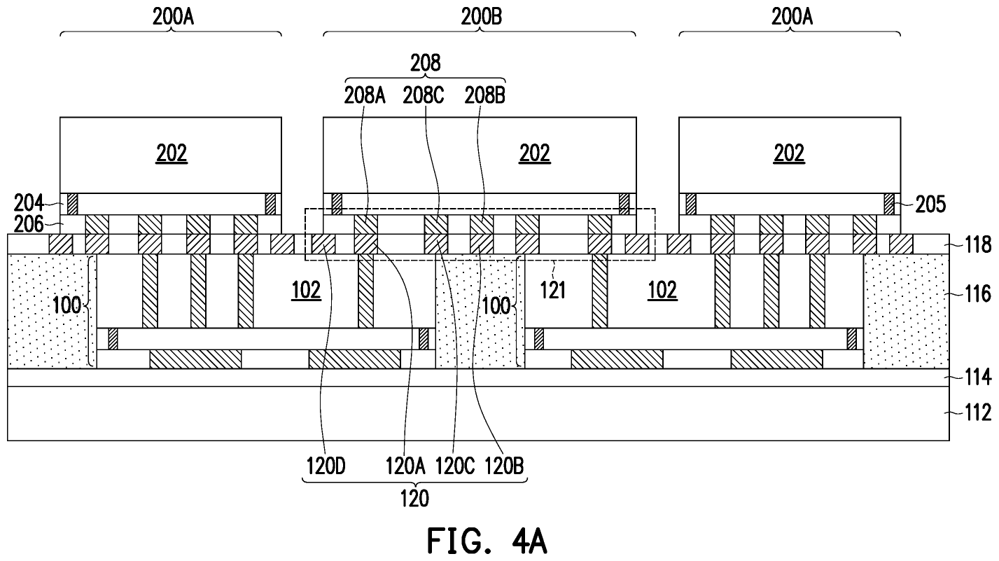

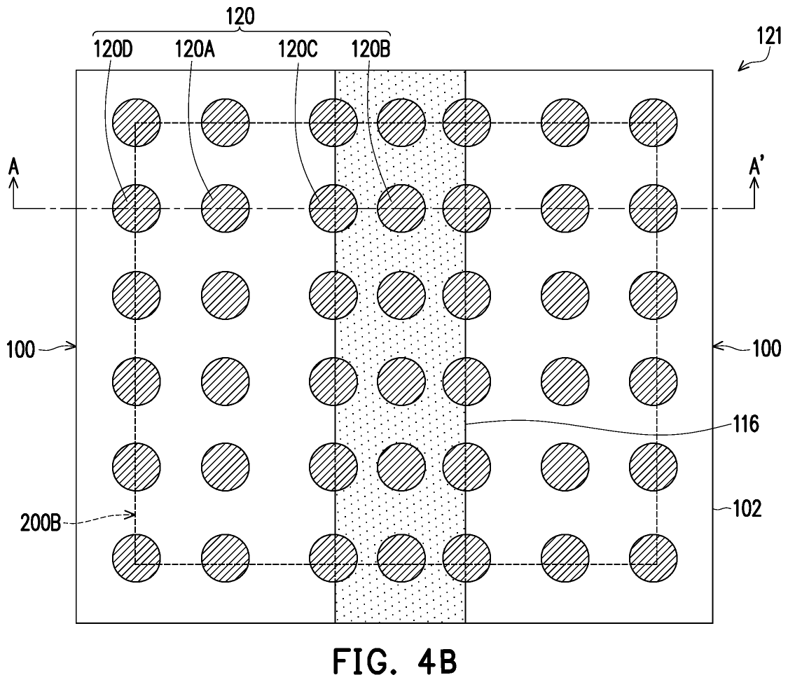

In FIG. 4A, upper integrated circuit dies 200 are bonded to the bonding layer 118 and the die connectors 120. The upper integrated circuit dies 200 may overlap the lower integrated circuit dies 100. For example, FIG. 4A illustrates embodiments in which the upper integrated circuit dies 200A overlap one lower integrated circuit die 100 and the upper integrated circuit die 200B overlap two lower integrated circuit dies 100. Each of the two upper integrated circuit dies 200A may be electrically coupled to the corresponding lower integrated circuit dies 100 underneath. The upper integrated circuit die 200B may be electrically coupled to both of the lower integrated circuit dies 100. As a result, the lower integrated circuit dies 100 may be electrically coupled to each other by the upper integrated circuit die 200B. In some embodiments, the upper integrated circuit die 200B does not comprise any active devices and thus may be referred to as a bridge die or silicon bridge. In some embodiments, the upper integrated circuit die 200B comprises active devices may be referred to as an active integrated circuit die. The layout of the upper integrated circuit dies 200 on the bonding layer 118 shown in FIG. 4A is an example, and other layouts are contemplated.

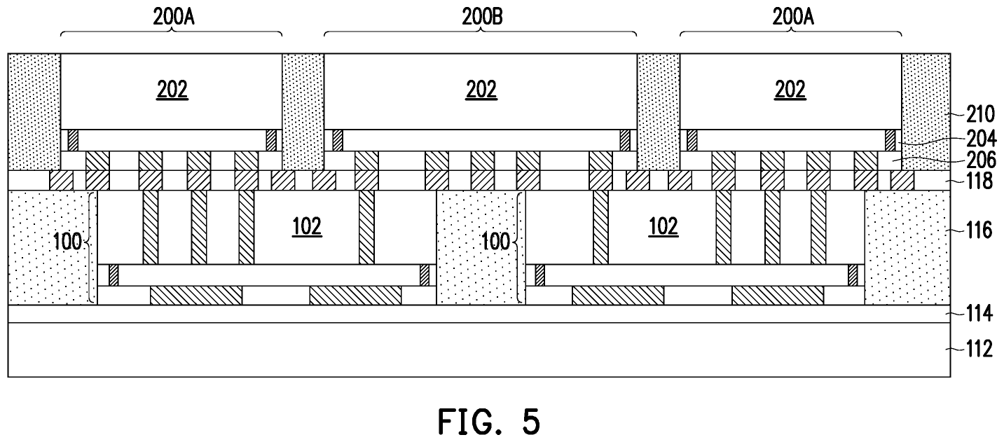

Each upper integrated circuit die 200 may be a logic die (e.g., CPU, GPU, SoC, AP, microcontroller, etc.), a memory die (e.g., DRAM die, SRAM die, etc.), a power management die (e.g., PMIC die), a RF die, a sensor die, a MEMS die, a signal processing die (e.g., DSP die), a front-end die (e.g., AFE die), the like, or combinations thereof. The materials and manufacturing processes of the features in the upper integrated circuit dies 200 may be found by referring to the like features in the lower integrated circuit die 100. Each upper integrated circuit die 200 may include a semiconductor substrate 202, which may have an active surface (e.g., the surface facing downwards in FIG. 5), which may be called a front side, and an inactive surface (e.g., the surface facing upwards in FIG. 5), which may be called a back side. The back side of the semiconductor substrate 202 may also be referred to as a back side of the upper integrated circuit die 200 and the front side of the semiconductor substrate 202 may face a front side of the upper integrated circuit die 200.

Devices (not separately illustrated) may be disposed at the active surface of the semiconductor substrate 202. The devices may be active devices (e.g., transistors, diodes, etc.), capacitors, resistors, or the like. An interconnect structure 204 may be disposed on the active surface of the semiconductor substrate 202. The interconnect structure 204 may interconnect the devices to form an integrated circuit. The interconnect structure 204 may comprise metallization patterns (not separately shown) in dielectric layers (not separately shown). The metallization patterns may be electrically coupled to the devices. A bonding layer 206 may be disposed on the interconnect structure 204, at the front side of the upper integrated circuit die 200. One or more passivation layer(s) (not separately illustrated) may be disposed between the bonding layer 206 and the interconnect structure 204.

Die connectors 208 may extend through the bonding layer 206 may be electrically coupled to the metallization patterns of the interconnect structure 204. The die connectors 208 may be referred to as bonding pads. The die connectors 208 may comprise active die connectors 208A, dummy die connectors 208B, and dummy die connectors 208C. The active die connectors 208A may be the die connectors 208 that are electrically coupled with the active die connectors 120A. The dummy die connectors 208B the dummy die connectors 208C may be the die connectors 120 that are in contact with the dummy die connectors 120B and the dummy die connectors 120C, respectively, in the bonding layer 118. The active die connectors 120A and active die connectors 208A may be electrically coupled to the circuitry of the lower integrated circuit dies 100 and/or circuitry of the upper integrated circuit dies 200. The dummy die connectors 120B and dummy die connectors 208B may be electrically isolated from the circuitry of the lower integrated circuit dies 100 and the circuitry of the upper integrated circuit dies 200.

A seal ring 205 may extend through the interconnect structure 204 of each upper integrated circuit die 200. The seal ring 205 may encircle the metallization patterns of the corresponding interconnect structure 204 in the top-down view and a region between the seal ring 205 and the metallization patterns may be referred to as the KOZ. The seal ring 205 may be formed of the same or similar material and by the same or similar process as the metallization patterns. The seal ring 205 may be electrically isolated from the devices.

The upper integrated circuit dies 200 may be bonded to the bonding layer 118 and the die connectors 120 by placing the upper integrated circuit dies 200 using a pick-and-place process or the like, then bonding the upper integrated circuit dies 200 to the bonding layer 118 and the die connectors 120. The bonding layers 206 of the upper integrated circuit dies 200 may be directly bonded to the bonding layer 118 through dielectric-to-dielectric bonding, and the die connectors 208 of the upper integrated circuit dies 200 may be directly bonded to respective die connectors 120 through metal-to-metal bonding. In the embodiments illustrated in FIG. 4A, the size and shape of the die connectors 208 are the same or similar to the respective die connectors 120. In other embodiments, the shape of the die connectors 208 is the same or similar to the respective die connectors 120 and the size (e.g., width) of the die connectors 208 is smaller than the respective die connectors 120.

The bonding may include a pre-bonding and an annealing. During the pre-bonding, a small pressing force may be applied to press the upper integrated circuit dies 200 against the bonding layer 118 and the die connectors 120, such as the active die connectors 120A, the dummy die connectors 120B, and the dummy die connectors 120C. The pre-bonding may be performed at a low temperature, such as room temperature. After the pre-bonding, direct bonds such as dielectric-to-dielectric bonds may be formed between the bonding layers 206 and the bonding layer 118. The bonding strength between the bonding layers 206 and the bonding layer 118 may be then improved in a subsequent annealing step at a higher temperature. The die connectors 208 may be in physical contact with the die connectors 120 after the pre-bonding, or may expand to be brought into physical contact with the die connectors 120 during the annealing. Further, during the annealing, the material of the die connectors 208 may intermingle or bond with the material of the die connectors 120, so that metal-to-metal bonds may be formed. During the annealing step, the bonding layer 118 may also bond with portions of the dummy die connectors 120D that are in contact with the bonding layer 118 by dielectric-to-metal bonds.

The dummy die connectors 208C of upper integrated circuit dies 200 may be bonded to the dummy die connectors 120C over interfaces between the lower integrated circuit dies 100 and the lower gap-fill layer 116. The bonded pairs of dummy die connectors 120C and dummy die connectors 208C directly over the interfaces between the lower integrated circuit dies 100 and the lower gap-fill layer 116 may eliminate or reduce the effect of the CTE mismatch between the materials underneath, such as components of the lower integrated circuit dies 100 (e.g., the semiconductor substrates 102) and the lower gap-fill layer 116 on the bonding integrity between the upper integrated circuit dies 200 and the bonding layer 118 as well as the die connectors 120, thereby eliminating or reducing the risk of the delamination of the upper integrated circuit dies 200 during the manufacturing and the operation of the integrated circuit package. As a result, better reliability of the integrated circuit package may be achieved.

FIG. 4A illustrates a front-to-back bonding configuration as an example, wherein the back sides of the lower integrated circuit dies 100 face the front sides of the upper integrated circuit dies 200 after bonding. Other bonding configurations may be used, such as a front-to-front bonding configuration or other bonding configuration. In the front-to-front bonding configuration the front sides of lower integrated circuit die 100 may face the front sides of the upper integrated circuit dies 200.

FIG. 4B shows a top-down view of the region 121 of the structure shown in FIG. 4A in accordance with some embodiments, in which the die connectors 120 are in an array. The cross-sectional view shown in FIG. 4A may be obtained along reference cross-section A-A′ in FIG. 4B. The bonding layer 118 is omitted and the upper integrated circuit die 200B as well as the portions of the interfaces between the lower integrated circuit dies 100 and the lower gap-fill layer 116 underneath the dummy die connectors 120C are shown in dash lines in FIG. 4B for illustrative purposes. As shown in FIG. 4B, the active die connectors 120A, the dummy die connectors 120B, and the dummy die connectors 120C are completely covered by the upper integrated circuit die 200B, and the dummy die connectors 120D are partially covered by the upper integrated circuit die 200B. In the embodiments illustrated in FIG. 4B, the dummy die connectors 120D may be a plurality of discrete pads which form a frame and extends underneath the edges of the upper integrated circuit die 200B. In other embodiments, the dummy die connectors 120D may be a plurality of discrete pads which are underneath the corners of the upper integrated circuit die 200B. In yet other embodiments, the dummy die connectors 120D may be a continuous frame and extends underneath the edges of the upper integrated circuit die 200B. The number of the die connectors 120 underneath the upper integrated circuit die 200B is provided as an example, and other numbers are contemplated.

In FIG. 5, an upper gap-fill layer 210 is formed around the upper integrated circuit dies 200. The upper gap-fill layer 210 may encircle the upper integrated circuit dies 200 in the top-down view. The upper gap-fill layer 210 may extend along sidewalls of the upper integrated circuit dies 200 (e.g., the semiconductor substrates 202, the interconnect structure 204, and the bonding layer 206). The exposed portions of the dummy die connectors 120D may be in contact with the upper gap-fill layer 210. As a result, the dummy die connectors 120D may be in contact with interfaces between upper integrated circuit dies 200 (e.g., the bonding layers 206) and the upper gap-fill layer 210. The upper gap-fill layer 210 may be formed by the same or similar method and formed of the same or similar dielectric material as the lower gap-fill layer 116. A thinning process may be performed to remove portions of the back sides of the semiconductor substrates 202 and the upper gap-fill layer 210. The thinning process may be, a CMP, a grinding process, an etch-back process, combinations thereof, or the like. After the thinning process, surfaces of the upper gap-fill layer 210, and the upper integrated circuit dies 200 (including the semiconductor substrates 202) are substantially coplanar (within process variations).

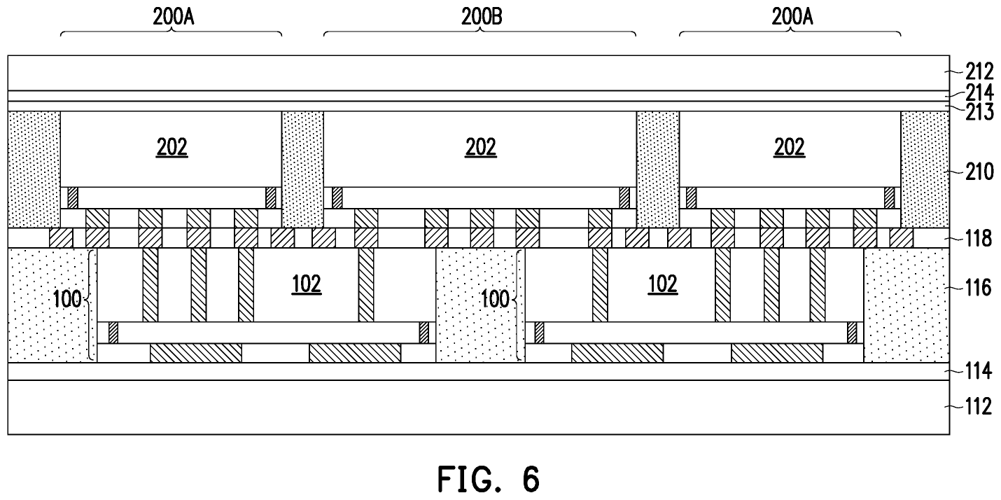

In FIG. 6, a carrier 212 is bonded to the upper surfaces of the semiconductor substrates 202 and the upper gap-fill layer 210. The carrier 212 may be a semiconductor carrier, a glass carrier, a ceramic carrier, or the like. The carrier 212 may be a wafer having the same or similar size as the carrier 112. In some embodiments, the carrier 212 is bonded to the semiconductor substrates 202 and the upper gap-fill layer 210 using bonding layers 213 and 214. The bonding layer 213 is formed on the semiconductor substrates 202 and the upper gap-fill layer 210, and the bonding layer 214 is formed on the carrier 212. The bonding layer 213 and the bonding layer 214 may each comprise a dielectric material, such as silicon dioxide or the like, and may be formed by a suitable deposition process such as CVD, ALD, or the like. The structure over the carrier 112 may be bonded to the carrier 212 by bonding the bonding layer 213 and the bonding layer 214 by the same or similar process used for bonding the bonding layer 118 and the bonding layer 206 described with respect to FIG. 4A.

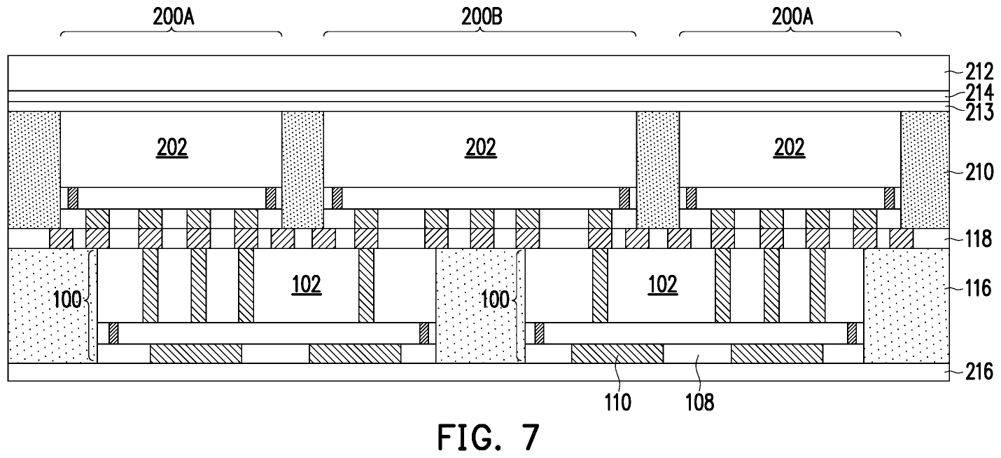

In FIG. 7, the carrier 112 and the adhesive 114 is removed, and a dielectric layer 216 is formed on the lower gap-fill layer 116 and the front sides of the lower integrated circuit dies 100. The removal process may include projecting a light beam such as a laser beam or a UV light beam on the adhesive 114 (shown in FIG. 6) so that the adhesive 114 decomposes upon exposure to the light beam and the carrier 112 may be removed. In some embodiments, the dielectric layer 216 comprises PBO, polyimide, a BCB-based polymer, or the like, and is formed by a suitable coating process such as spin coating, lamination, or the like. In some embodiments, the dielectric layer 216 comprises silicon dioxide, silicon nitride, or the like, and is formed by a suitable deposition process such as CVD, ALD, or the like. In some embodiments, a redistribution structure (not separately illustrated) may be formed prior to forming the dielectric layer 216 to provide additional routing.

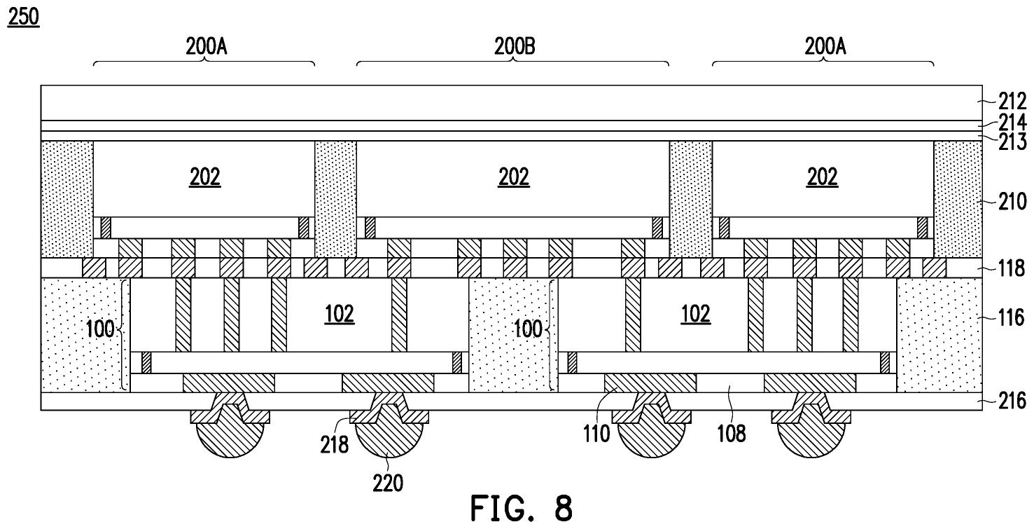

In FIG. 8, under-bump metallizations (UBMs) 218 and electrical connectors 220 are formed. The UBMs 218 may have portions extending along a surface of the dielectric layer 216 and portions extending through the dielectric layer 216 to physically and electrically couple to the die connectors 110 and the die connectors 110. As a result, the UBMs 218 are electrically coupled to the lower integrated circuit dies 100.

As an example to form the UBMs 218, the dielectric layer 216 may be patterned to form openings exposing the underlying die connectors 110 and die connectors 110. The patterning may be done by an acceptable photolithography and etching processes, such as forming a mask then performing an anisotropic etching. The mask may be removed after the patterning. A seed layer (not separately illustrated) may be formed on the dielectric layer 216, in the openings through the dielectric layer 216, and on the exposed portions of the die connectors 110 and the die connectors 110. The seed layer may be a metal layer, which may be a single layer or a composite layer comprising a plurality of sub-layers formed of different materials. In some embodiments, the seed layer comprises a titanium layer and a copper layer over the titanium layer. The seed layer may be formed using a suitable deposition process, such as physical vapor deposition (PVD) or the like. A photoresist may be then formed and patterned on the seed layer. The photoresist may be formed by spin coating or the like and may be exposed to light for patterning. The pattern of the photoresist may correspond to the UBMs 218. The patterning may form openings through the photoresist to expose the seed layer.

A conductive material may be formed in the openings of the photoresist and on the exposed portions of the seed layer. The conductive material may be formed by plating, such as electroless plating, electroplating, or the like. The conductive material may comprise a metal or a metal alloy, such as copper, titanium, tungsten, aluminum, the like, or combinations thereof. Then the photoresist and portions of the seed layer on which the conductive material is not formed may be removed. The photoresist may be removed by an acceptable ashing or stripping process, such as using an oxygen plasma or the like. Once the photoresist is removed, portions of the seed layer on which the conductive material is not formed may be removed by an acceptable etching process, such as by wet or dry etching. The remaining portions of the seed layer and conductive material may form the UBMs 218.

Electrical connectors 220 may be formed on the UBMs 218. The electrical connectors 220 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the electrical connectors 220 comprise a conductive material such as solder, copper, aluminum, gold, nickel, silver, palladium, tin, the like, or a combination thereof. The electrical connectors 220 may be formed by initially forming a layer of solder through evaporation, electroplating, printing, solder transfer, ball placement, or the like. Once the layer of solder has been formed on the structure, a reflow may be performed to shape the solder into the desired bump shapes. In some embodiments, the electrical connectors 220 comprise metal pillars, such as a copper pillar, formed by a sputtering, printing, electroplating, electroless plating, CVD, or the like, which are solder free and have substantially vertical sidewalls. A metal cap layer may be formed on top of the metal pillars. The metal cap layer may include nickel, tin, tin-lead, gold, silver, palladium, indium, nickel-palladium-gold, nickel-gold, the like, or a combination thereof, and may be formed by a plating process. The structure shown in FIG. 8 may be referred to as a wafer structure 250.

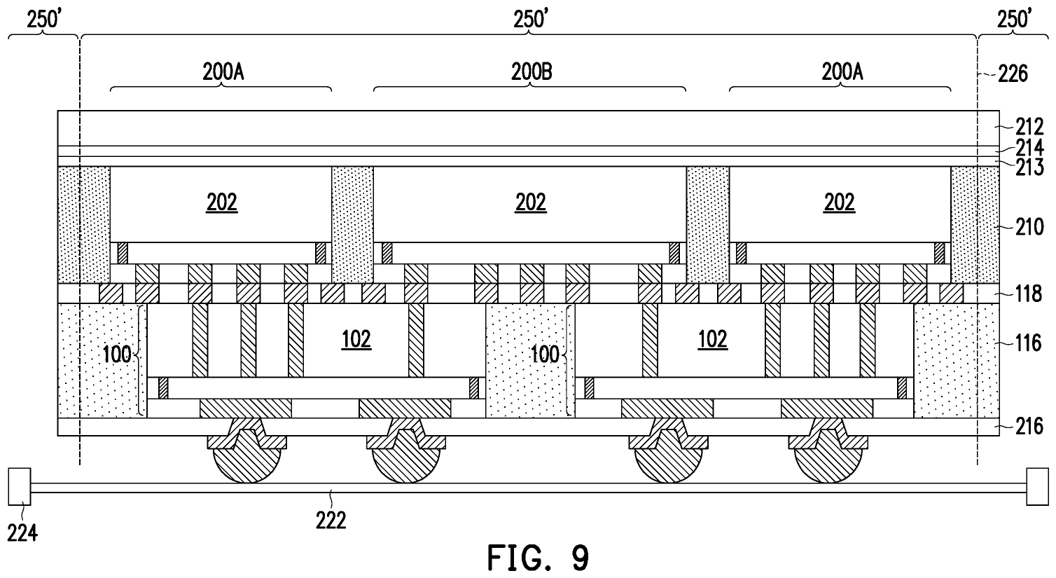

In FIG. 9, the wafer structure 250 is singulated to form individual integrated circuit package components 250′. The processes discussed above may be performed using wafer-level processing. The carrier 212 may be a wafer and may include many structures (not separately illustrated) similar to the one illustrated in FIG. 8. The wafer structure 250 may be placed on a tape 222 supported by a frame 224. The wafer structure 250 may be then singulated along scribe lines 226, so that the wafer structure 250 may be separated into discrete integrated circuit package components 250′. The singulation process may include a sawing process, a laser cutting process, or the like. A cleaning process or rinsing process may be performed after the singulation process.

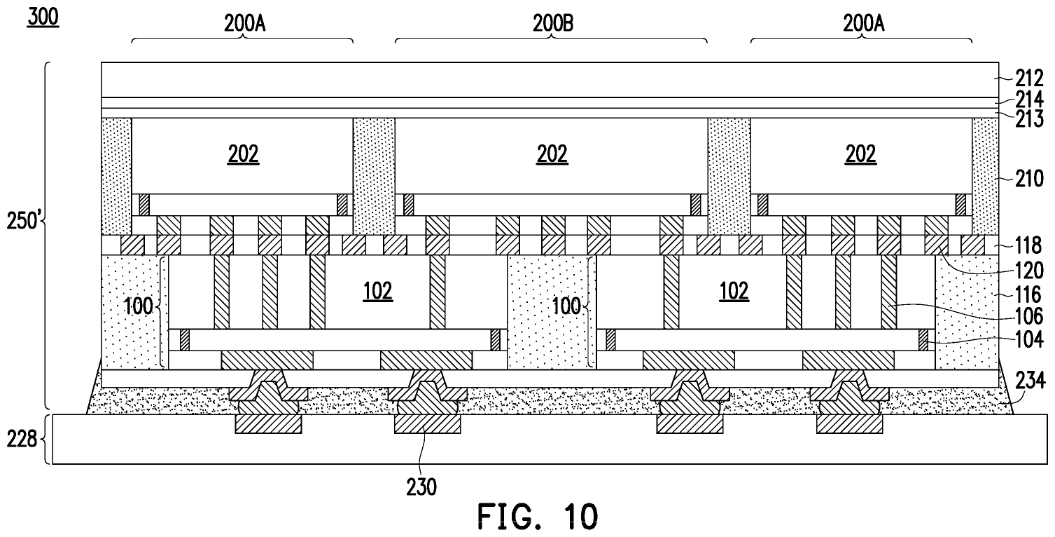

In FIG. 10, the integrated circuit package component 250′ is bonded to a package substrate 228 and an underfill 234 is formed between the integrated circuit package component 250′ and the package substrate 228. The package substrate 228 may comprise conductive pads 230. In some embodiments, the package substrate 228 comprise materials such as fiberglass reinforced resin, bismaleimide-triazine (BT) resin, other printed circuit board (PCB) materials, or the like. In some embodiments, the package substrate 228 comprise materials such as silicon, germanium, silicon germanium, silicon carbide, gallium arsenic, indium arsenide, indium phosphide, silicon germanium carbide, gallium arsenic phosphide, gallium indium phosphide, or the like.

The package substrate 228 may include active and passive devices (not separately illustrated), such as transistors, capacitors, resistors, combinations thereof, or the like. The devices may be formed using any suitable methods. The package substrate 228 may comprise metallization layers and vias (not separately illustrated) physically and electrically coupled to the conductive pads 230. The metallization layers may be formed over the active and passive devices and may connect the various devices to form functional circuitry. The metallization layers may be alternating layers of dielectric material (e.g., low-k dielectric material) and conductive material (e.g., copper) with vias interconnecting the layers of conductive material. In some embodiments, the package substrate 228 is free of active and passive devices.

During the bonding process the electrical connectors 220 may be reflowed to bond the integrated circuit package component 250′ to the conductive pads 230. The electrical connectors 220 may electrically and physically couple the package substrate 228 to the integrated circuit package component 250′. In some embodiments, a solder resist (not separately illustrated) is formed on the package substrate 228. The electrical connectors 220 may be disposed in openings in the solder resist to electrically and physically couple to the conductive pads 230. The solder resist may be used to protect areas of the package substrate 228 from external damage.

The underfill 234 may surround the electrical connectors 220 and protect the joints resulting from the reflowing of the electrical connectors 220. The underfill 234 may encircle the integrated circuit package component 250′ in the top-down view. The underfill 234 may be formed by a capillary flow process after the integrated circuit package component 250′ is attached or by a suitable deposition method before the integrated circuit package component 250′ is attached. The underfill 234 may be subsequently cured. The structure shown in FIG. 10 may be referred to as an integrated circuit package 300.

Various embodiments are described above in the context of a system on integrated chips (SoIC) package configuration. It should be understood that various embodiments may also be adapted to apply to other package configurations, such as integrated fan-out on substrate (InFO), chip on wafer on substrate (CoWoS) or the like.

The embodiments may have some advantageous features. By forming the dummy die connectors 120C directly over the interfaces between the lower integrated circuit dies 100 and the lower gap-fill layer 116, the effect of the CTE mismatch between components of the lower integrated circuit dies 100 (e.g., the semiconductor substrates 102) and the lower gap-fill layer 116 on the bonding integrity between the upper integrated circuit dies 200 and the bonding layer 118 as well as the die connectors 120 may be eliminated or reduced, thereby eliminating or reducing the risk of the delamination of the upper integrated circuit dies 200 during the manufacturing and the operation of the integrated circuit package 300. As a result, better reliability of the integrated circuit package 300 may be achieved.

In an embodiment, an integrated circuit package includes a first die; a first gap-fill layer along sidewalls of the first die; a first bonding layer on the first die and the first gap-fill layer; and a first die connector in the first bonding layer, wherein the first die connector is directly over an interface between the first die and the first gap-fill layer. In an embodiment, the first die includes a first semiconductor substrate, wherein the first die connector is in contact with the first semiconductor substrate and the first gap-fill layer. In an embodiment, the first die connector is electrically isolated from circuitry of the first die. In an embodiment, the integrated circuit package further includes a second die connector and a third die connector in the first bonding layer, wherein the first die connector is between the second die connector and the third die connector, wherein the second die connector and the third die connector are the closest die connectors to the first die connector along a first direction, where in the second die connector is electrically coupled to circuitry of the first die, and wherein the third die connector is over the first gap fill layer, the third connector being electrically isolated from the circuitry of the first die. In an embodiment, the second die connector is spaced apart from the first die connector by a first distance and the third die connector is spaced apart from the first die connector by a second distance, and wherein the first distance is larger than the second distance. In an embodiment, the second die connector is spaced apart from the first die connector by a first distance and the third die connector is spaced apart from the first die connector by a second distance, and wherein the first distance is equal to the second distance. In an embodiment, the integrated circuit package further includes a second die bonded to the first bonding layer, and a second gap-fill layer on the first bonding layer, the second gap fill layer extending along sidewalls of the second die.

In an embodiment, an integrated circuit package includes a first die, wherein the first die further includes a first semiconductor substrate; a first gap-fill layer on sidewalls of the first die; a first bonding layer on the first gap-fill layer and the first semiconductor substrate; a first die connector in the first bonding layer, wherein the first die connector is in contact with an interface between the first die and the first gap-fill layer; and a second die including a second bonding layer and a second die connector in the second bonding layer, wherein the second bonding layer is bonded to the first bonding layer and the second die connector is bonded to the first die connector. In an embodiment, a coefficient of thermal expansion of the first gap-fill layer is different from a coefficient of thermal expansion of the first semiconductor substrate. In an embodiment, the interface between the first die and the first gap-fill layer divides the first die connector into two portions of a same size in a top-down view. In an embodiment, the interface between the first die and the first gap-fill layer divides the first die connector into two portions of different sizes in a top-down view. In an embodiment, the first die connector is a dummy die connector. In an embodiment, the integrated circuit package further includes a second gap-fill layer on sidewalls of the second die, wherein the second gap-fill layer extends over a third die connector in the first bonding layer, wherein the third die connector is in contact with an interface between the second die and the second gap-fill layer.

In an embodiment, a method of forming an integrated circuit package includes attaching a first die to a carrier, wherein the first die includes a first substrate, wherein the first substrate includes a semiconductor material; forming a first gap-fill layer on a first sidewall of the first die, wherein the first gap-fill layer includes a dielectric material; forming a first bonding layer on a top surface of the first die and a top surface of the first gap-fill layer; and forming a first die connector in the first bonding layer, wherein the first die connector overlaps an interface between the first die and the first gap-fill layer in a top-down view. In an embodiment, the first die connector contacts the first substrate and the first gap-fill layer. In an embodiment, the method further includes attaching a second die to the carrier, wherein the second die includes a second substrate, wherein a first portion of the first gap-fill layer is between the first sidewall of the first die and a first sidewall of the second die, and wherein forming the first bonding layer includes forming the first bonding layer on a top surface of the second die; and forming a second die connector in the first bonding layer, wherein the second die connector overlaps an interface between the second die and the first gap-fill layer in the top-down view. In an embodiment, the method further includes forming a third die connector in the first bonding layer, wherein the third die connector is between the first sidewall of the first die and the first sidewall of the second die. In an embodiment, the method further includes bonding a third die to the first bonding layer, the first die connector, the second die connector, and the third die connector using dielectric-to-dielectric bonding and metal-to-metal bonding. In an embodiment, the first die connector, the second die connector, and the third die connector are isolated from circuitry of the first die, circuitry of the second die, and circuitry of the third die. In an embodiment, the method further includes forming a second die connector in the first bonding layer, wherein a first conductive via of the first die extends through the first substrate and contacts the second die connector in the first bonding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit package, comprising:
a first die;
a first gap-fill layer along sidewalls of the first die;
a first bonding layer on the first die and the first gap-fill layer; and
a first die connector in the first bonding layer, wherein the first die connector is directly over an interface between the first die and the first gap-fill layer.

2. The integrated circuit package of claim 1, wherein the first die comprises a first semiconductor substrate, wherein the first die connector is in contact with the first semiconductor substrate and the first gap-fill layer.

3. The integrated circuit package of claim 1, wherein the first die connector is electrically isolated from circuitry of the first die.

4. The integrated circuit package of claim 1, further comprising a second die connector and a third die connector in the first bonding layer, wherein the first die connector is between the second die connector and the third die connector, wherein the second die connector and the third die connector are the closest die connectors to the first die connector along a first direction, wherein the second die connector is electrically coupled to circuitry of the first die, and wherein the third die connector is over the first gap fill layer, the third connector being electrically isolated from the circuitry of the first die.

5. The integrated circuit package of claim 4, wherein the second die connector is spaced apart from the first die connector by a first distance and the third die connector is spaced apart from the first die connector by a second distance, and wherein the first distance is larger than the second distance.

6. The integrated circuit package of claim 4, wherein the second die connector is spaced apart from the first die connector by a first distance and the third die connector is spaced apart from the first die connector by a second distance, and wherein the first distance is equal to the second distance.

7. The integrated circuit package of claim 1, further comprising:
a second die bonded to the first bonding layer, and
a second gap-fill layer on the first bonding layer, the second gap fill layer extending along sidewalls of the second die.

8. An integrated circuit package, comprising:
a first die, wherein the first die further comprises a first semiconductor substrate;
a first gap-fill layer on sidewalls of the first die;
a first bonding layer on the first gap-fill layer and the first semiconductor substrate;
a first die connector in the first bonding layer, wherein the first die connector is in contact with an interface between the first die and the first gap-fill layer; and
a second die comprising a second bonding layer and a second die connector in the second bonding layer, wherein the second bonding layer is bonded to the first bonding layer and the second die connector is bonded to the first die connector.

9. The integrated circuit package of claim 8, wherein a coefficient of thermal expansion of the first gap-fill layer is different from a coefficient of thermal expansion of the first semiconductor substrate.

10. The integrated circuit package of claim 8, wherein the interface between the first die and the first gap-fill layer divides the first die connector into two portions of a same size in a top-down view.

11. The integrated circuit package of claim 8, wherein the interface between the first die and the first gap-fill layer divides the first die connector into two portions of different sizes in a top-down view.

12. The integrated circuit package of claim 8, wherein the first die connector is a dummy die connector.

13. The integrated circuit package of claim 8, further comprising a second gap-fill layer on sidewalls of the second die, wherein the second gap-fill layer extends over a third die connector in the first bonding layer, wherein the third die connector is in contact with an interface between the second die and the second gap-fill layer.

14. A method of forming an integrated circuit package, the method comprising:
attaching a first die to a carrier, wherein the first die comprises a first substrate, wherein the first substrate comprises a semiconductor material;
forming a first gap-fill layer on a first sidewall of the first die, wherein the first gap-fill layer comprises a dielectric material;
forming a first bonding layer on a top surface of the first die and a top surface of the first gap-fill layer; and
forming a first die connector in the first bonding layer, wherein the first die connector overlaps an interface between the first die and the first gap-fill layer in a top-down view.

15. The method of claim 14, wherein the first die connector contacts the first substrate and the first gap-fill layer.

16. The method of claim 14, further comprising:
attaching a second die to the carrier, wherein the second die comprises a second substrate, wherein a first portion of the first gap-fill layer is between the first sidewall of the first die and a first sidewall of the second die, and wherein forming the first bonding layer comprises forming the first bonding layer on a top surface of the second die; and
forming a second die connector in the first bonding layer, wherein the second die connector overlaps an interface between the second die and the first gap-fill layer in the top-down view.

17. The method of claim 16, further comprising forming a third die connector in the first bonding layer, wherein the third die connector is between the first sidewall of the first die and the first sidewall of the second die.

18. The method of claim 17, further comprising bonding a third die to the first bonding layer, the first die connector, the second die connector, and the third die connector using dielectric-to-dielectric bonding and metal-to-metal bonding.

19. The method of claim 18, wherein the first die connector, the second die connector, and the third die connector are isolated from circuitry of the first die, circuitry of the second die, and circuitry of the third die.

20. The method of claim 14, further comprising forming a second die connector in the first bonding layer, wherein a first conductive via of the first die extends through the first substrate and contacts the second die connector in the first bonding layer.
